(19) United States
(12) Patent Application Publication
(10) Pub. No.: US 2025/0218744 A1
(43) Pub. Date: Jul. 3, 2025

(54) PLASMA PROCESSING APPARATUS

(71) Applicant: Tokyo Electron Limited, Tokyo (JP)

(72) Inventor: Naoki MATSUMOTO, Miyagi (JP)

(73) Assignee: Tokyo Electron Limited, Tokyo (JP)

(21) Appl. No.: 19/083,581

(22) Filed: Mar. 19, 2025

Related U.S. Application Data
(63) Continuation of application No. PCT/JP2023/032647, filed on Sep. 7, 2023.

(30) Foreign Application Priority Data
Sep. 30, 2022 (JP) 2022-157994

(51) Int. Cl. H01J 37/32

(52) U.S. Cl. CPC H01J 37/32669; H01J 37/3211; H01J 37/32174; H01J 37/32724; H01J 2237/334

(57) ABSTRACT

A plasma processing apparatus includes: a plasma process chamber; a substrate support disposed within the plasma process chamber; an antenna disposed above the plasma process chamber; a source RF signal generator configured to generate a source RF signal; a bias signal generator configured to generate a bias signal; an upper electromagnet unit including a plurality of upper annular electromagnets arranged concentrically; a sidewall electromagnet unit including a plurality of sidewall annular electromagnets; an electromagnet excitation circuit configured to supply a current to at least one of the plurality of upper annular electromagnets or the plurality of sidewall annular electromagnets; and a controller configured to adjust the current supplied to at least one of the plurality of upper annular electromagnets or the plurality of sidewall annular electromagnets to control a plasma electron density distribution in the plasma process chamber.

### CROSS-REFERENCE TO RELATED APPLICATIONS

The application is a Bypass Continuation application of PCT International Application No. PCT/JP2023/032647, filed on Sep. 7, 2023 and designating the United States, the international application being based upon and claiming the benefit of priority from Japanese Patent Application No. 2022-157994, filed on Sep. 30, 2022, the entire contents of each are incorporated herein by reference.

### TECHNICAL FIELD

Exemplary embodiments of the present disclosure relate to a plasma processing apparatus.

### BACKGROUND

As a technique for appropriately controlling a ratio of ions and radicals that reach a workpiece, there is a plasma processing apparatus disclosed in Patent Document 1.

### PRIOR ART DOCUMENTS

### Patent Documents

Patent Document 1: Japanese Laid-open Patent Publication No. 2018-98094

### SUMMARY

According to one embodiment of the present disclosure, there is provided a plasma processing apparatus including: a plasma process chamber; a substrate support disposed within the plasma process chamber; an antenna disposed above the plasma process chamber; a source RF signal generator electrically connected to the antenna and configured to generate a source RF signal; a bias signal generator electrically connected to the substrate support and configured to generate a bias signal; an upper electromagnet unit disposed above the antenna and including a plurality of upper annular electromagnets arranged concentrically; a sidewall electromagnet unit disposed to surround a sidewall of the plasma process chamber and including a plurality of sidewall annular electromagnets arranged along a vertical direction; an electromagnet excitation circuit configured to supply a current to at least one of the plurality of upper annular electromagnets or the plurality of sidewall annular electromagnets; and a controller configured to adjust the current supplied to at least one of the plurality of upper annular electromagnets or the plurality of sidewall annular electromagnets to control a plasma electron density distribution in the plasma process chamber.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram for explaining an exemplary configuration of a plasma processing system.

FIG. 2 is a diagram for explaining an exemplary configuration of an inductively coupled plasma processing apparatus.

FIG. 3 is a diagram showing an example of a top surface of a substrate support.

FIG. 4 is a diagram showing an example of a cross section of the substrate support.

FIG. 5 is a block diagram showing an example of a configuration of a control board.

FIG. 6 is a flowchart showing an example of a plasma processing method according to an exemplary embodiment.

FIG. 7 is a flowchart showing an example of step ST1.

FIG. 8 is a timing chart showing an example of a source RF signal, a current U, and a current S.

FIG. 9 is a flowchart showing an example of step ST3.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Each embodiment of the present disclosure will be described below.

In one exemplary embodiment, there is provided a plasma processing apparatus. The plasma processing apparatus includes: a plasma process chamber; a substrate support disposed within the plasma process chamber; an antenna disposed above the plasma process chamber; a source RF signal generator electrically connected to the antenna and configured to generate a source RF signal; a bias signal generator electrically connected to the substrate support and configured to generate a bias signal; an upper electromagnet unit disposed above the antenna and including a plurality of upper annular electromagnets arranged concentrically; a sidewall electromagnet unit disposed to surround a sidewall of the plasma process chamber and including a plurality of sidewall annular electromagnets arranged along a vertical direction; an electromagnet excitation circuit configured to supply a current to at least one of the plurality of upper annular electromagnets or the plurality of sidewall annular electromagnets; and a controller configured to adjust the current supplied to at least one of the plurality of upper annular electromagnets or the plurality of sidewall annular electromagnets to control a plasma electron density distribution in the plasma process chamber.

In one exemplary embodiment, the plurality of upper annular electromagnets includes: a first upper annular electromagnet; a second upper annular electromagnet disposed to surround the first upper annular electromagnet; a third upper annular electromagnet disposed to surround the second upper annular electromagnet; and a fourth upper annular electromagnet disposed to surround the third upper annular electromagnet.

In one exemplary embodiment, the plurality of sidewall annular electromagnets includes: a first sidewall annular electromagnet; a second sidewall annular electromagnet disposed below the first sidewall annular electromagnet; and a third sidewall annular electromagnet disposed below the second sidewall annular electromagnet.

In one exemplary embodiment, the substrate support includes a plurality of heaters, and the controller is further configured to: acquire a power value supplied to each of the plurality of heaters; and adjust the current supplied to at least one of the plurality of upper annular electromagnets or the plurality of sidewall annular electromagnets based on the acquired power value.

In one exemplary embodiment, the source RF signal repeats a first state having a first power level and a second state having a second power level smaller than the first power level, and the current repeats a first state having a first current level and a second state having a second current level smaller than the first current level based on the first state and the second state of the source RF signal.

In one exemplary embodiment, the first power level is a zero power level, and the first current level is a zero current level.

In one exemplary embodiment, the controller is configured to adjust the current supplied to at least one of the plurality of upper annular electromagnets or the plurality of sidewall annular electromagnets in a plasma ignition sequence.

In one exemplary embodiment, a plasma processing apparatus includes: a plasma process chamber; a substrate support disposed within the plasma process chamber; an antenna disposed above the plasma process chamber; a source RF signal generation electrically connected to the antenna and configured to generate a source RF signal; a bias signal generation electrically connected to the substrate support and configured to generate a bias signal; an upper electromagnet unit disposed above the antenna including a plurality of upper annular electromagnets arranged concentrically; and an electromagnet excitation circuit configured to supply a current to at least one of the plurality of upper annular electromagnets.

In one exemplary embodiment, the plurality of upper annular electromagnets includes: a first upper annular electromagnet; and a second upper annular electromagnet disposed to surround the first upper annular electromagnet.

In one exemplary embodiment, the plurality of upper annular electromagnets further includes: a third upper annular electromagnet disposed to surround the second upper annular electromagnet; and a fourth upper annular electromagnet disposed to surround the third upper annular electromagnet.

In one exemplary embodiment, the substrate support includes a plurality of heaters, and the plasma processing apparatus further includes: a controller configured to acquire a power value supplied to each of the plurality of heaters and adjust the current supplied to at least one of the plurality of upper annular electromagnets based on the acquired power value.

In one exemplary embodiment, a plasma processing apparatus includes: a plasma process chamber; a substrate support disposed within the plasma process chamber; an antenna disposed above the plasma process chamber; a source RF signal generator electrically connected to the antenna and configured to generate a source RF signal; a bias signal generator electrically connected to the substrate support and configured to generate a bias signal; a sidewall electromagnet unit disposed to surround a sidewall of the plasma process chamber and including a plurality of sidewall annular electromagnets arranged along a vertical direction; and an electromagnet excitation circuit configured to supply a current to at least one of the plurality of sidewall annular electromagnets.

In one exemplary embodiment, the plurality of sidewall annular electromagnets include: a first sidewall annular electromagnet; and a second sidewall annular electromagnet disposed below the first sidewall annular electromagnet.

In one exemplary embodiment, the plurality of sidewall annular electromagnets further include: a third sidewall annular electromagnet disposed below the second sidewall annular electromagnet.

In one exemplary embodiment, the substrate support includes a plurality of heaters, and the plasma processing apparatus further includes: a controller configured to acquire a power value supplied to each of the plurality of heaters and adjust the current supplied to at least one of the plurality of sidewall annular electromagnets based on the acquired power value.

Hereinafter, each embodiment of the present disclosure will be described in detail with reference to the drawings. Further, the same or similar elements in the drawings are denoted by the same reference numerals, and explanation thereof will be omitted. Unless otherwise specified, positional relationships such as up, down, left, right, etc. will be described based on the positional relationships shown in the drawings. Dimensional ratios in the drawings do not indicate actual ratios, and the actual ratios are not limited to the ratios shown in the drawings.

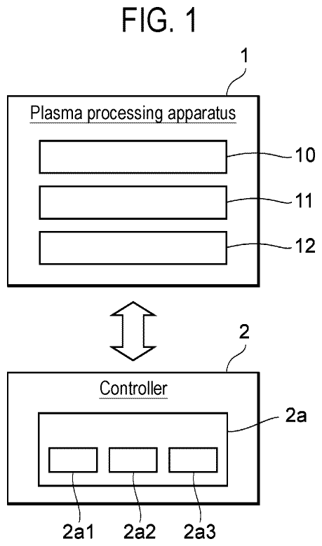

FIG. 1 is a diagram for explaining an exemplary configuration of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma process chamber 10, a substrate support 11, and a plasma generator 12. The plasma process chamber 10 has a plasma processing space. The plasma process chamber 10 also has at least one gas supply port for supplying at least one process gas into the plasma processing space, and at least one gas discharging hole for discharging a gas from the plasma processing space. The gas supply port is connected to a gas supply 20 to be described later, and the gas discharging hole is connected to an exhaust system 40 to be described later. The substrate support 11 is disposed in the plasma processing space and has a substrate support surface for supporting a substrate.

The plasma generator 12 is configured to generate plasma from at least one process gas supplied into the plasma processing space. The plasma formed in the plasma processing space may be capacitively coupled plasma (CCP), inductively coupled plasma (ICP), electron-cyclotron-resonance plasma (ECR plasma), helicon wave excited plasma (HWP), surface wave plasma (SWP), etc. In addition, various types of plasma generators may be used, including an alternating current (AC) plasma generator and a direct current (DC) plasma generator. In one embodiment, an AC signal (AC power) used in the AC plasma generator has a frequency in a range of 100 kHz to 10 GHz. Thus, the AC signal includes a radio frequency (RF) signal and a microwave signal. In one embodiment, the RF signal has a frequency in a range of 100 kHz to 150 MHz.

The controller 2 processes computer-executable instructions that cause the plasma processing apparatus 1 to perform various steps described in the present disclosure. The controller 2 may be configured to control elements of the plasma processing apparatus 1 to perform the various steps described herein. In one embodiment, a part or all of the controller 2 may be included in the plasma processing apparatus 1. The controller 2 may include a processor 2a1, a storage 2a2, and a communication interface 2a3. The controller 2 is realized by, for example, a computer 2a. The processor 2al may be configured to read a program from the storage 2a2 and execute the read program to perform various control operations. This program may be stored in the storage 2a2 in advance, or may be acquired via a medium when necessary. The acquired program is stored in the storage 2a2 and is read and executed from the storage 2a2 by the processor 2a1. The medium may be various non-transitory storage medium readable by the computer 2a, or may be a communication line connected to the communication interface 2a3. The processor 2al may be a CPU (Central Processing Unit). The storage 2a2 may include a RAM (Random Access Memory), a ROM (Read Only Memory), a HDD (Hard Disk Drive), an SSD (Solid State Drive), or a combination thereof. The communication interface 2a3 may communicate with the plasma processing apparatus 1 via a communication line such as a LAN (Local Area Network).

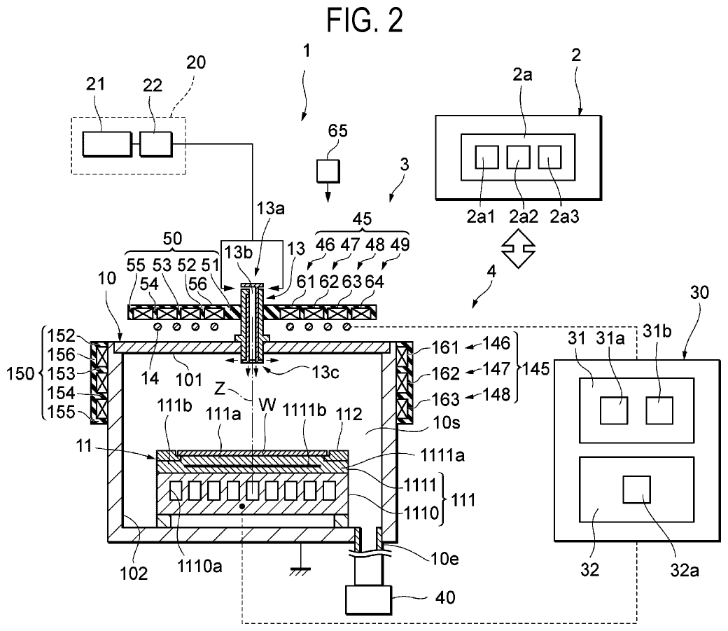

Below, an exemplary configuration of a capacitively coupled plasma processing apparatus as an example of the plasma processing apparatus 1 will be described. FIG. 2 is a diagram for explaining the exemplary configuration of a capacitively coupled plasma processing apparatus.

The capacitively coupled plasma processing apparatus 1 includes a plasma process chamber 10, a gas supply 20, a power supply 30, and an exhaust system 40. The plasma process chamber 10 includes a dielectric window 101. The plasma processing apparatus 1 also includes a substrate support 11, a gas introducer, and an antenna 14. The substrate support 11 is disposed in the plasma process chamber 10. The antenna 14 is disposed on or above the plasma process chamber 10 (i.e., on or above the dielectric window 101). The plasma process chamber 10 has a plasma processing space 10s defined by the dielectric window 101, a sidewall 102 of the plasma process chamber 10, and the substrate support 11. The plasma process chamber 10 is grounded.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also called a substrate support surface for supporting the substrate W, and the annular region 111b is also called a ring support surface for supporting the ring assembly 112.

In one embodiment, the main body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a and an electrostatic electrode 1111b disposed within the ceramic member 1111a. The ceramic member 1111a includes the central region 111a. In one embodiment, the ceramic member 1111a also includes an annular region 111b. Note that other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to an RF power supply 31 and/or a DC power supply 32 to be described later may be disposed within the ceramic member 1111a. In this case, the at least one RF/DC electrode functions as a bias electrode. Note that the conductive member of the base 1110 and the at least one RF/DC electrode may function as a plurality of bias electrodes. In addition, the electrostatic electrode 1111b may function as a bias electrode. Thus, the substrate support 11 includes at least one bias electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

The substrate support 11 may also include a temperature adjustment module configured to adjust at least one of the electrostatic chuck 1111, the ring assembly 112, or the substrate to a target temperature. The temperature adjustment module may include a heater, a heat transfer medium, a flow passage 1110a, or a combination thereof. A heat transfer fluid such as brine or a gas flows through the flow passage 1110a. In one embodiment, the flow passage 1110a is formed in the base 1110, and one or more heaters are disposed within the ceramic member 1111a of the electrostatic chuck 1111. The substrate support 11 may also include a heat transfer gas supply configured to supply a heat transfer gas to a gap between a back surface of the substrate W and the central region 111a.

The gas introducer is configured to introduce at least one process gas from the gas supply 20 into the plasma processing space 10s. In one embodiment, the gas introducer includes a center gas injector (CGI) 13. The center gas injector 13 is disposed above the substrate support 11 and is installed in a central opening formed in the dielectric window 101. The center gas injector 13 includes at least one gas supply port 13a, at least one gas passage 13b, and at least one gas introduction port 13c. The process gas supplied to the gas supply port 13a passes through the gas passage 13b and is introduced from the gas introduction port 13c into the plasma processing space 10s. The gas introducer may include, in addition to or instead of the center gas injector 13, one or more side gas injectors (SGIs) attached to one or more openings formed in the sidewall 102.

The gas supply 20 may include at least one gas source 21 and at least one flow rate controller 22. In one embodiment, the gas supply 20 is configured to supply at least one process gas from the corresponding gas source 21 to the gas introducer via the corresponding flow rate controller 22. Each flow rate controller 22 may include, for example, a mass flow controller or a pressure-controlled flow rate controller. Further, the gas supply 20 may include at least one flow modulation device that modulates or pulses the flow rate of at least one process gas.

The power supply 30 includes an RF power supply 31 coupled to the plasma process chamber 10 via at least one impedance matching circuit. The RF power supply 31 is configured to supply at least one RF signal (RF power) to at least one bias electrode and/or the antenna 14. This causes plasma to be formed from at least one process gas supplied to the plasma processing space 10s. Thus, the RF power supply 31 may function as at least a portion of the plasma generator 12. In addition, by supplying a bias RF signal to at least one bias electrode, a bias potential is generated on the substrate W, and ions in the formed plasma may be attracted to the substrate W.

In one embodiment, the RF power supply 31 includes a first RF generator 31a and a second RF generator 31b. The first RF generator 31a is configured to be coupled to the antenna 14 via at least one impedance matching circuit so as to generate a source RF signal (source RF power) for plasma generation. In one embodiment, the source RF signal has a frequency in a range of 10 MHz to 150 MHz. In one embodiment, the first RF generator 31a may be configured to generate a plurality of source RF signals having different frequencies. The generated one or more source RF signals are supplied to the antenna 14.

The second RF generator 31b is configured to be coupled to at least one bias electrode via at least one impedance matching circuit so as to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The generated one or more bias RF signals are supplied to at least one bias electrode. In various embodiments, at least one of the source RF signal or the bias RF signal may be pulsed.

The power supply 30 may also include a DC power supply 32 coupled to the plasma process chamber 10. The DC power supply 32 includes a bias DC generator 32a. In one embodiment, the bias DC generator 32a is configured to be connected to at least one bias so as to generate a bias DC signal. The generated bias DC signal is applied to the at least one bias electrode.

In various embodiments, the bias DC signal may be pulsed. In this case, a sequence of voltage pulses is applied to the at least one bias electrode. The voltage pulses may have a pulse waveform that is rectangular, trapezoidal, triangular, or a combination thereof. In one embodiment, a waveform generator for generating a sequence of voltage pulses from a DC signal is connected between the bias DC generator 32a and at least one bias electrode. Thus, the bias DC generator 32a and the waveform generator constitute a voltage pulse generator. The voltage pulse may have a positive polarity or a negative polarity. In addition, the sequence of voltage pulses may include one or more positive voltage pulses and one or more negative voltage pulses in one period. Further, the bias DC generator 32a may be provided in addition to the RF power supply 31, or may be provided instead of the second RF generator 31b.

The antenna 14 includes one or more coils. In one embodiment, the antenna 14 may include an outer coil and an inner coil arranged coaxially. In this case, the RF power supply 31 may be connected to both the outer coil and the inner coil, or to either the outer coil or the inner coil. In the former case, the same RF generator may be connected to both the outer coil and the inner coil, or separate RF generators may be connected to the outer coil and the inner coil separately.

The exhaust system 40 may be connected to, for example, a gas discharging hole 10e formed in a bottom of the plasma process chamber 10. The exhaust system 40 may include a pressure regulating valve and a vacuum pump. The internal pressure of the plasma processing space 10s is adjusted by the pressure regulating valve. The vacuum pump may include a turbo molecular pump, a dry pump, or a combination of these.

The plasma processing apparatus 1 includes an upper electromagnet assembly 3 and a sidewall electromagnet assembly 4. The upper electromagnet assembly 3 and the sidewall electromagnet assembly 4 are configured to generate a magnetic field in the chamber 10. The upper electromagnet assembly 3 includes one or more upper electromagnet units 45. The upper electromagnet assembly 3 also includes a bobbin 50. The sidewall electromagnet assembly 4 includes one or more sidewall electromagnet units 145. The sidewall electromagnet assembly 4 also includes a bobbin 150.

The upper electromagnet assembly 3 is disposed on or above the plasma process chamber 10. In the example shown in FIG. 2, the upper electromagnet assembly 3 is disposed above the antenna 14.

The upper electromagnet unit 45 includes electromagnets 46 to 49. The electromagnets 46 to 49 are an example of upper annular electromagnets. The electromagnets 46 to 49 are configured to include coils 61 to 64. The coils 61 to 64 are wound around a central axis Z. The central axis Z may be an axis passing through the center of the substrate W or the substrate support 11. That is, in the upper electromagnet assembly 3, the coils 61 to 64 may be annular coils. The coils 61 to 64 may be arranged coaxially in the radial direction around the central axis Z at the same height position.

The upper electromagnet assembly 3 is configured to further include the bobbin 50 (or a yoke). The coils 61 to 64 are wound around the bobbin 50 (or a yoke). The bobbin 50 is made of, for example, a magnetic material. The bobbin 50 is arranged to surround the center gas injector 13. The bobbin 50 has a central portion 51, cylindrical portions 52 to 55, and a base portion 56. The base portion 56 has a cylindrical shape, and includes a central axis aligned with the central axis Z. That is, the base portion 56 has an opening formed at the center of the base portion 56, and the center of the opening is substantially aligned with the central axis Z. The center gas injector 13 is disposed inside the opening of the base portion 56.

The central portion 51 and the cylindrical portions 52 to 55 extend downward from a lower surface of the base portion 56. The central portion 51 has a cylindrical shape, and includes a central axis that is substantially aligned with the central axis Z. That is, the central portion 51 has an opening formed at the center of the central portion 51, and the center of the opening is substantially aligned with the central axis Z. The center gas injector 13 is disposed inside the opening of the central portion 51. The diameter of the opening of the central portion 51 may be the same as the diameter of the opening of the base portion 56.

The cylindrical portions 52 to 55 extend radially outward of the central portion 51 with respect to the central axis Z. The cylindrical portions 52 to 55 are arranged concentrically around the central axis Z. That is, the cylindrical portion 52 is arranged to surround the central portion 51 and the coil 61. The cylindrical portion 53 is arranged to surround the cylindrical portion 52 and the coil 62. The cylindrical portion 54 is arranged to surround the cylindrical portion 53 and the coil 63. The cylindrical portion 55 is arranged to surround the cylindrical portion 54 and the coil 64.

The coil 61 is wound along an outer peripheral surface of the central portion 51. The coil 61 is accommodated in a groove between the central portion 51 and the cylindrical portion 52. The coil 62 is wound along an outer peripheral surface of the cylindrical portion 52. The coil 62 is accommodated in a groove between the cylindrical portion 52 and the cylindrical portion 53. The coil 63 is wound along an outer peripheral surface of the cylindrical portion 53. The coil 63 is accommodated in a groove between the cylindrical portion 53 and the cylindrical portion 54. The coil 64 is wound along an outer peripheral surface of the cylindrical portion 54. The coil 64 is accommodated in a groove between the cylindrical portion 54 and the cylindrical portion 55.

A current source 65 is connected to the coils 61 to 64. The current source 65 is an example of an electromagnet excitation circuit. The controller 2 controls the supply and stop of a current from the current source 65 to the coils 61 to 64, the direction of the current, and a current value. A single current source may be connected to the coils 61 to 64, or different current sources may be connected to the coils 61 to 64 individually.

The upper electromagnet unit 45 may form a magnetic field, which is symmetrical with respect to the central axis Z, in the chamber 10. By controlling the current supplied to each of the coils 61 to 64, the strength distribution (or magnetic flux density) of the magnetic field may be adjusted in the radial direction with respect to the central axis Z. This allows the plasma processing apparatus 1 to adjust the radial distribution of the density of plasma generated in the plasma process chamber 10.

The sidewall electromagnet unit 145 includes electromagnets 146 to 148. The electromagnets 146 to 148 are an example of sidewall annular electromagnets. The electromagnets 146 to 148 include coils 161 to 163. The coils 161 to 163 are wound around the central axis Z to surround the plasma process chamber 10. The coils 161 to 163 may be annular coils. The coils 161 to 163 are arranged at the same position in the radial direction. That is, the coils 161 to 163 may be arranged coaxially in the height direction around the central axis Z.

The sidewall electromagnet assembly 4 is configured to further include a bobbin 150 (or a yoke). The coils 161 to 163 are wound around the bobbin 150 (or a yoke). The bobbin 150 is made of, for example, a magnetic material. The bobbin 150 is disposed to surround a sidewall 102 of the plasma process chamber 10. The bobbin 150 includes cylindrical portions 152 to 155 and a base portion 156. The base portion 156 has a cylindrical shape, and its central axis is aligned with the central axis Z. That is, the base portion 156 has an opening formed at the center of the base portion 156, and the center of the opening is approximately aligned with the central axis Z. The plasma process chamber 10 is disposed inside the opening of the base portion 156.

The cylindrical portions 152 to 155 extend from the inside of the base portion 156 in the direction of the central axis Z. The cylindrical portions 152 to 155 are disposed at the same positions in the radial direction relative to the central axis Z. That is, the cylindrical portions 152 to 155 are disposed so as to overlap each other in a plan view of the plasma process chamber 10 seen from above. The cylindrical portion 152 is disposed above the coil 161. The cylindrical portion 153 is disposed below the cylindrical portion 152 and the coil 161. The cylindrical portion 154 is disposed below the cylindrical portion 153 and the coil 162. The cylindrical portion 155 is disposed below the cylindrical portion 154 and the coil 163.

The coils 161 to 163 are wound along an outer peripheral surface of the sidewall 102 of the plasma process chamber 10. The coil 161 is accommodated in a groove between the cylindrical portion 152 and the cylindrical portion 153. The coil 162 is accommodated in a groove between the cylindrical portion 153 and the cylindrical portion 154. The coil 163 is accommodated in a groove between the cylindrical portion 154 and the cylindrical portion 155. The coils 161 to 163 are connected to a current source 65. The controller 2 controls the supply and stop of a current from the current source 65 to the coils 161 to 163, the direction of the current, and a current value. A single current source may be connected to the coils 161 to 163, or different current sources may be connected to the coils 161 to 163 individually.

The sidewall electromagnet unit 145 may form a magnetic field, which is symmetrical with respect to the central axis Z, in the chamber 10. By controlling the current supplied to each of the coils 161 to 163, the strength distribution (or magnetic flux density) of the magnetic field may be adjusted in the direction along the central axis Z. This allows the plasma processing apparatus 1 to adjust the distribution of the density of plasma generated in the plasma process chamber 10 in the thickness direction of the plasma.

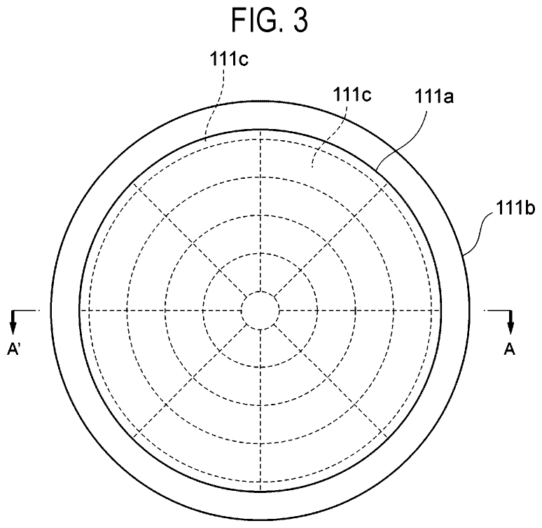

FIG. 3 is a diagram showing an example of a top surface of the substrate support 11. As shown in FIG. 3, the substrate support 11 includes the central region 111a for supporting the substrate W and the annular region 111b for supporting the ring assembly 112. The central region 111a includes a plurality of zones 111c as shown by broken lines in FIG. 3. In this embodiment, the temperature adjustment module may control the temperature of the substrate W or the substrate support 11 in units of zones 111c. The number of zones 111c and the area and shape of each zone 111c may be appropriately set according to the conditions required for controlling the temperature of the substrate W.

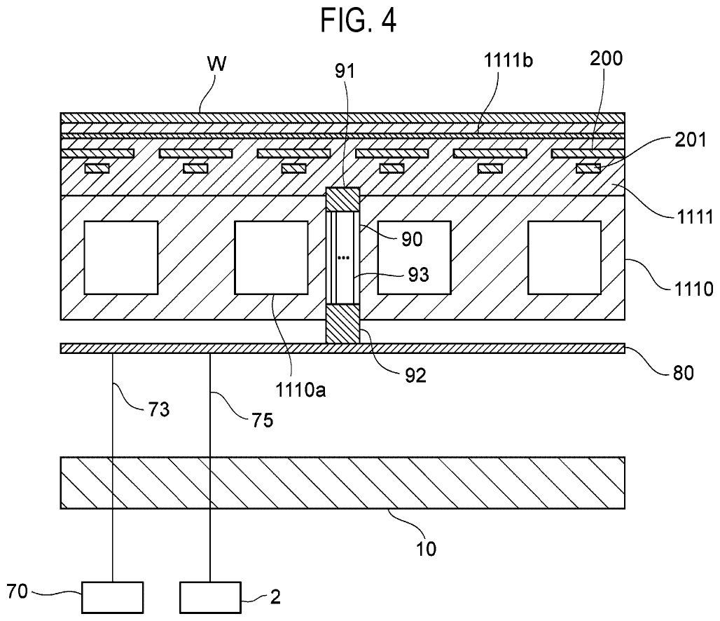

FIG. 4 is a diagram showing an example of a cross section of the substrate support 11. FIG. 4 shows a portion of the cross section of the substrate support 11 at A-A′ in FIG. 3. As shown in FIG. 4, the substrate support 11 has the electrostatic chuck 1111, the base 1110, and a control board 80. The electrostatic chuck 1111 has a plurality of heaters 200 and a plurality of resistors 201 therein. In this embodiment, in each zone 111c shown in FIG. 2, one heater 200 and one resistor 201 are arranged inside the electrostatic chuck 1111. In each zone 111c, the resistor 201 is disposed in a vicinity of the heater 200. In one example, the resistor 201 may be disposed between the heater 200 and the base 1110 and at a position closer to the heater 200 than the base 1110. The resistor 201 is configured so that its resistance value changes according to a temperature. In one example, the resistor 201 may be a thermistor.

The base 1110 has one or more through-holes 90 penetrating from an upper surface (a surface facing the electrostatic chuck 1111) to a lower surface (a surface facing the control board 80) of the base 1110. The plurality of heaters 200 and the plurality of resistors 201 may be electrically connected to the control board 80 via the through-holes 90. In this embodiment, a connector 91 is fitted into one end of an upper surface side of the through-hole 90, and a connector 92 is fitted into one end of a lower surface side of the through-hole 90. The plurality of heaters 200 and the plurality of resistors 201 are electrically connected to the connector 91. The plurality of heaters 200 and the plurality of resistors 201 may be connected to the connector 91 via, for example, wirings arranged inside the electrostatic chuck 1111. The connector 92 is electrically connected to the control board 80. In addition, a plurality of wirings 93 that electrically connect the connector 91 and the connector 92 are arranged in the through-hole 90. As a result, the plurality of heaters 200 and the plurality of resistors 201 may be electrically connected to the control board 80 via the through-holes 90. The connector 92 may function as a support member that fixes the control board 80 to the base 1110.

The control board 80 is a board on which elements that control the plurality of heaters 200 and/or the plurality of resistors 201 are arranged. The control board 80 may be arranged to face the lower surface of the base 1110 and in parallel to the lower surface. The control board 80 may be disposed to be surrounded by a conductive member. The control board 80 may be supported on the base 1110 by a support member other than the connector 92.

The control board 80 may be electrically connected to a power supply 70 via a wiring 73. That is, the power supply 70 may be electrically connected to the plurality of heaters 200 via the control board 80. The power supply 70 generates power to be supplied to the plurality of heaters 200. As a result, the power supplied from the power supply 70 to the control board 80 may be supplied to the plurality of heaters 200 via the connector 92, the wiring 93, and the connector 91. An RF filter that reduces RF may be disposed between the power supply 70 and the control board 80. The RF filter may be provided outside the plasma process chamber 10.

In addition, the control board 80 may be communicatively connected to the controller 2 via a wiring 75. The wiring 75 may be optical fiber. In this case, the control board 80 communicates with the controller 2 by optical communication. In addition, the wiring 75 may be metal wiring.

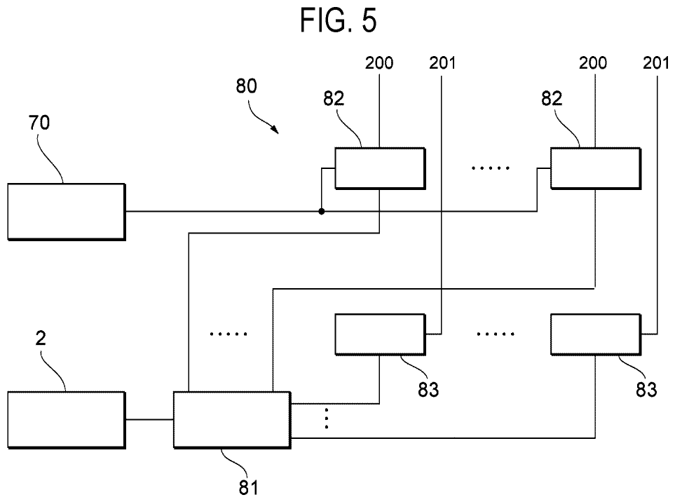

FIG. 5 is a block diagram showing an exemplary configuration of the control board 80. The control board 80 includes a controller 81, and further includes a plurality of supplies 82 and a plurality of measurers 83, which are examples of elements. The plurality of supplies 82 and the plurality of measurers 83 are provided to correspond to the plurality of heaters 200 and the plurality of resistors 201, respectively. One supply 82 and one measurer 83 may be provided for one heater 200 and one resistor 201, respectively.

Each measurer 83 generates a voltage based on the resistance value of each resistor 201 provided to correspond to the measurer 83, and supplies the generated voltage to the controller 81. The measurer 83 may be configured to convert the voltage generated according to the resistance value of the resistor 201 into a digital signal and output the digital signal to the controller 81.

### <Example of Plasma Processing Method>

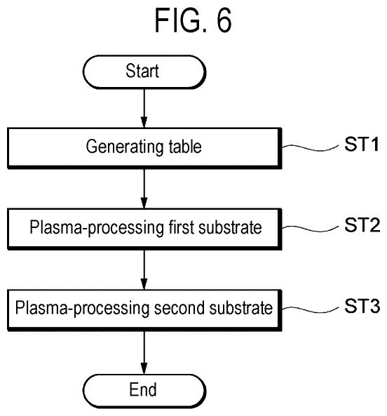

FIG. 6 is a flowchart showing a plasma processing method (hereinafter also referred to as the “present processing method”) according to an exemplary embodiment. As shown in FIG. 6, the present processing method includes step ST1 of generating a table, step ST2 of plasma-processing a first substrate, and step ST3 of plasma-processing a second substrate. The processing in each step may be performed in the plasma processing system shown in FIG. 1. In the following, as an example, the controller 2 controls each part of the plasma processing apparatus 1 to perform the present processing method.

### (Step ST1: Generating Table)

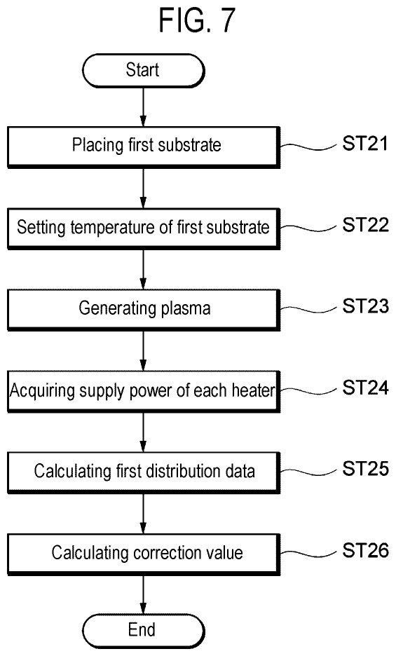

FIG. 7 is a flowchart showing an example of step ST1. A table generated in step ST1 may be a table that stores a change amount of one or more parameters related to plasma generation and a change amount of ion flux distribution caused by the change amount of the one or more parameters in association with each other. The ion flux is an ion flux generated between the substrate W placed on the substrate support 11 and the plasma generated in the plasma process chamber 10. The ion flux may also include an ion flux generated between the ring assembly 112 and the plasma generated in the plasma process chamber 10.

The parameter may be, for example, a parameter capable of changing a distribution of electron density generated in the plasma process chamber 10, such as a magnetic flux density of a magnetic field applied in the plasma process chamber 10. The parameter may be a current and/or a voltage supplied to the coils 61 to 64 included in the upper electromagnet unit 45 and/or the coils 161 to 163 included in the sidewall electromagnet unit 145 in FIG. 2.

That is, in the table generated in step ST1, the parameter stored in association with the amount of change in ion flux may be the amount of change in magnetic flux density of the magnetic field applied in the plasma, or the amount of change in current and/or voltage supplied to the electromagnet generating the magnetic field. Here, when the temperature of the substrate W is constant, the ion flux Γᵢ generated between the substrate W and the plasma may have a relationship with the electron density in the plasma based on the following formula:

Γᵢ∝nₑ×(Vdc)^{1/2} Formula (1)

Here, nₑ is the electron density (m⁻³) in the plasma. Vdc is a bias voltage (V) generated between the substrate W and the plasma. In addition, the electron density in the plasma may have a relationship with the magnetic flux density of the magnetic field applied to the plasma based on the following formula:

nₑ∝H Formula (2)

Here, H is the magnetic flux density (G). As a result, the distribution of the magnetic flux density applied to the plasma may be changed, thereby changing the distribution of the ion flux generated between the plasma and the substrate W. In this way, in step ST1, the controller 2 may generate a table that, for example, associates the amount of change in the distribution of the magnetic flux density of the magnetic field applied to the plasma with the amount of change in the distribution of the ion flux.

In addition, the thickness S of an ion sheath and the electron density in the plasma may have a relationship based on the following formula:

S=(√2/3)×(ε₀Tₑ/eNₑ)^{1/2}×(2Vdc/Tₑ)^{3/4} Formula (3)

Here, co is the dielectric constant of a vacuum, Tₑ is the electron temperature, e is the elementary electron quantity, and Vdc is the bias voltage. Thus, by controlling the electron density in the plasma, the thickness of the ion sheath may be controlled. Then, by controlling the distribution of the thickness of the ion sheath, the angle of incidence of the ion flux with respect to the substrate may be controlled.

### (Step ST2: Plasma-Processing First Substrate)

FIG. 7 is a flowchart showing an example of step ST2. In step ST2, the first substrate is plasma-processed. The first substrate may be a substrate on which a semiconductor element is formed. The plasma processing may include a plasma etching process for forming a semiconductor element on the first substrate.

As shown in FIG. 7, step ST2 includes step ST21 of placing the first substrate, step ST22 of setting a temperature of the first substrate, step ST23 of generating plasma, step ST24 of acquiring the supply power of each heater, step ST25 of calculating first distribution data, and step ST26 of calculating a correction value. In one example, step ST2 may be performed to correct a change over time of the plasma processing apparatus 1.

First, in step ST21, the first substrate is placed on the substrate support 11. Next, in step ST22, the temperature of the first substrate is set. In one example, the controller 2 controls the controller 81 disposed on the control board 80 so that the temperature of the first substrate in each zone 111c becomes the set temperature. In addition, the controller 2 acquires the power supplied to each heater 200 in a state where the temperature of the first substrate is stable at the set temperature, and stores the acquired power in the storage 2a2.

After the temperature of the first substrate is stable at the set temperature, in step ST23, plasma is generated in the plasma process chamber 10 to plasma-process the first substrate. In one example, in step ST23, first, a process gas is supplied from the gas supply 20 into the plasma process chamber 10. Then, when a source RF signal is supplied to the antenna 14, plasma is generated from the process gas in the plasma processing space 10s. In addition, a current is supplied from the current source 65 to at least one of the coils 61 to 64 or the coils 161 to 163, so that a magnetic field may be formed in the plasma processing space 10s.

The source RF signal supplied to the antenna 14 may be a pulse wave that periodically includes power pulses. That is, the source RF signal may be a pulse wave that repeats a first state in which the power level is high and a second state in which the power level is lower than that in the first state. The power level may be, for example, an effective value of power of the source RF signal.

The current (hereinafter also referred to as “current U”) supplied from the current source 65 to the coils 61 to 64 of the upper electromagnet unit 45 and the current (hereinafter also referred to as “current S”) supplied from the current source 65 to the coils 161 to 163 of the sidewall electromagnet unit 145 may each be a pulse wave that periodically includes current pulses. That is, the current U and the current S may each be a pulse current that repeats a first state in which the current level is high and a second state in which the current level is lower than that in the first state. The current levels of the currents supplied to the coils 61 to 64 may be different from each other. In addition, the current levels of the currents supplied to the coils 161 to 163 may be different from each other.

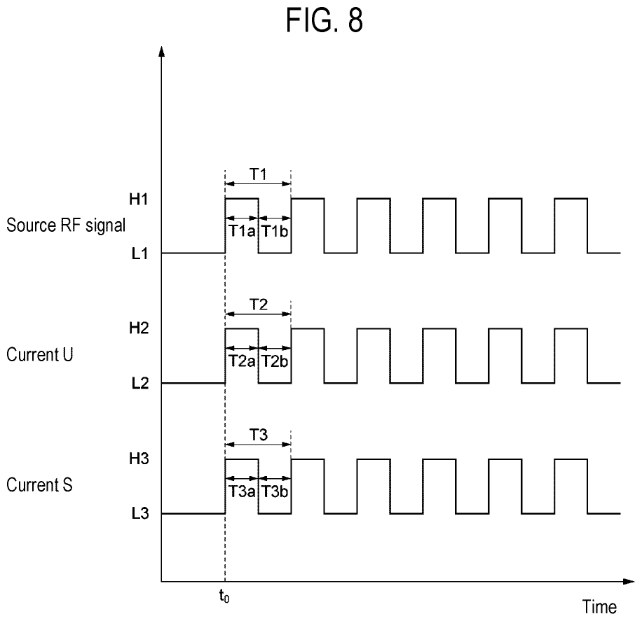

FIG. 8 is a timing chart showing an example of the source RF signal, the current U, and the current S. In FIG. 8, the vertical axis represents the power level of the source RF signal and the current levels of the currents U and S. The horizontal axis represents time.

In the example shown in FIG. 8, the source RF signal is a pulse wave having a repetition interval (period) T1. The repetition interval T1 includes an interval T1a in which the power level of the source RF signal is H1, and an interval T1b in which the power level of the source RF signal is L1 which is lower than H1. The power level L1 may be a zero power level.

In the example shown in FIG. 8, the current U is a pulse wave having a repetition interval (period) T2. The repetition interval T2 includes an interval T2a in which the current level of the current U is H2, and an interval T2b in which the current level of the current U is L2 which is lower than H2. The current S is a pulse wave having a repetition interval (period) T3. The repetition interval T3 includes an interval T3a in which the current level of the current S is H3, and an interval T3b in which the current level of the current S is L3 which is lower than H3. The current source 65 may adjust the current levels of the currents U and S depending on the coils to which the currents are supplied. The current levels L2 and L3 may be zero current levels.

In one embodiment, the lengths of the interval T2 and the interval T3 are equal to the length of the interval T1. In this case, the source RF signal has the power level H1 in the first interval T1a in each cycle T1 of a plurality of cycles, and the power level L1 in the second interval T1b in each cycle T1. In addition, the current U has the current level H2 in the first interval T1a (=T2a) in each cycle T1 (=T2), and the current level L2 in the second interval T1b (=T2b) in each cycle T1 (=T2). In addition, the current S has the current level H3 in the first interval T1a (=T3a) in each cycle T1 (=T3), and the current level L3 in the second interval T1b (=T3b) in each cycle T1 (=T3). In addition, the timing of the current pulse appearing in the current U may be synchronized with the timing of the power pulse appearing in the source RF signal. In addition, the timing of the current pulse appearing in the current S may be synchronized with the timing of the power pulse appearing in the source RF signal. In the example shown in FIG. 8, the timing of the power pulse appearing in the source RF signal is approximately the same as the timing of the current pulses appearing in the current U and the current S.

In one embodiment, the current levels of the current U and/or the current S may be adjusted in a plasma ignition sequence. The plasma ignition sequence may be, in one example, a sequence of operations including the supply of the source RF signal, frequency matching in the RF power supply 31, and/or impedance matching in a matching circuit coupled to the RF power supply 31.

Next, in step ST24 shown in FIG. 7, the power supplied to the plurality of heaters 200 is acquired. In steps ST23 and ST24, the controller 2 controls the power supplied to each heater 200 so that the temperature of the first substrate in each zone 111c becomes the set temperature. Then, in step ST24, the controller 2 acquires the power supplied to each of the plurality of heaters 200 in a state where plasma is generated. The controller 2 may store the power supplied to the plurality of heaters 200 acquired in step ST24 in the storage 2a2 in association with one or more parameters.

Next, in step ST25, the first distribution data is calculated. The first distribution data may be distribution data of ion flux generated between the plasma generated in the plasma process chamber 10 and the first substrate. Here, when the temperature of the first substrate placed on the substrate support 11 is constant, the ion flux Γᵢ (m⁻²s⁻¹) generated between the first substrate and the plasma generated in the plasma process chamber 10 may have the following relationship with the heat flux Γₕₑₐₜ (W/m²·s) generated between the first substrate and the plasma generated in the plasma process chamber 10.

Γᵢ×Vdc∝Γₕₑₐₜ Formula (4)

Here, Vdc (V) is the bias voltage (V) generated between the first substrate and the plasma. In addition, the heat flux Γₕₑₐₜ generated between the first substrate placed on the substrate support 11 and the plasma generated in the plasma process chamber 10 may be calculated based on the supply power acquired in step ST24. In one example, the heat flux Γₕₑₐₜ in each zone 111c may be calculated based on the following formula:

Γₕₑₐₜ=(P₀−Pₕₜᵣ)/A Formula (5)

Here, P₀ is the power (W) supplied to the heater 200 of the zone 111c in a state where plasma is not generated. That is, P₀ is the power supplied to the heater 200 of the zone 111c, which is acquired in step ST22. In addition, Pₕₜᵣ is the power (W) supplied to the heater 200 of the zone 111c in a state where plasma is generated. That is, Pₕₜᵣ is the power supplied to the heater 200 of the zone 111c, which is acquired in step ST24. As an example, Pₕₜᵣ may be the power (W) when the power (W) supplied to the heater 200 of the zone 111c after plasma is generated becomes approximately constant. A is the area (m₂) of the zone 111c.

Next, in the second substrate on which the plasma processing is performed after the first substrate, in step ST26, a correction value may be calculated based on the first distribution data so that the distribution of the ion flux may be corrected. In one example, the correction value may be a difference value between reference distribution data and the first distribution data. In one example, the reference distribution data may be distribution data of the ion flux acquired when the plasma processing apparatus 1 is in a normal state. The normal state of the plasma processing apparatus 1 includes, for example, after the installation or maintenance of the plasma processing apparatus 1.

### (Step ST3: Plasma-Processing Second Substrate)

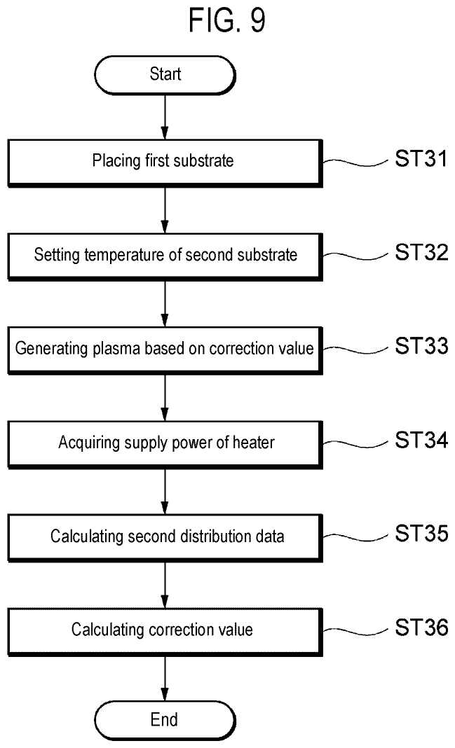

FIG. 9 is a flow chart showing an example of step ST3. In step ST3, the second substrate is plasma-processed. In step ST3, the second substrate may be plasma-processed using the correction value acquired for the first substrate in step ST26. In one example, the first substrate may be a substrate that is processed first in a specific lot. In addition, the second substrate may be a substrate that is processed after the first substrate in the specific lot.

As shown in FIG. 9, step ST3 includes step ST31 of placing the second substrate, step ST32 of setting the temperature of the second substrate, step ST33 of generating plasma based on a correction value, step ST34 of acquiring the supply power of each heater, step ST35 of calculating second distribution data, and step ST36 of calculating the correction value.

First, in step ST31, the second substrate is placed on the substrate support 11. Next, in step ST32, the temperature of the second substrate is set. In one example, the controller 2 controls the controller 81 disposed on the control board 80 so that the temperature of the second substrate in each zone 111c becomes a set temperature. In addition, the controller 2 acquires the power supplied to each heater 200 in a state where the temperature of the second substrate is stable at the set temperature, and stores the acquired power in the storage 2a2.

After the temperature of the second substrate is stabilized at the set temperature, in step ST33, plasma is generated in the plasma process chamber 10 to plasma-process the second substrate. Some of parameters for plasma-processing the second substrate in step ST33 may be set based on the correction value calculated based on the reference distribution data in step ST26. That is, in step ST33, the plasma may be generated in the plasma process chamber 10 based on the correction value calculated based on the reference distribution data in step ST25. As an example, when the correction value is a difference value between the reference distribution data and the first distribution data (a difference value of the distribution of the ion flux), the controller 2 refers to the amount of change in the distribution of the ion flux corresponding to the correction value in the table stored in the storage 2a2 in step ST1. Then, the controller 2 sets a parameter for correcting the distribution of the ion flux based on the amount of change in the parameter corresponding to the amount of change in the distribution of the ion flux included in the table.

In one example, the parameter may be the magnetic flux density of the magnetic field applied in the plasma, or the current and/or voltage supplied to the electromagnet generating the magnetic field. In one example, the controller 2 may adjust the current level of the current supplied to at least one of the coils 61 to 64 of the upper electromagnet unit 45 or the coils 161 to 163 of the sidewall electromagnet unit 145 based on the correction value. This may correct the distribution of the electron density in the plasma and correct the distribution of the ion flux. In addition, the distribution of the electron density in the plasma is corrected and the distribution of the thickness of an ion sheath is corrected. This corrects the angle of incidence of the ion flux with respect to the substrate. Further, this may reduce a variation in the angle of a recess formed in the substrate by, for example, plasma etching.

Next, in step ST34, the power supplied to the plurality of heaters 200 is acquired. In steps ST33 and ST34, the controller 2 controls the power supplied to each heater 200 so that the temperature of the second substrate in each zone 111c becomes the set temperature. Then, the controller 2 acquires the power supplied to each of the plurality of heaters 200 in a state where plasma is generated. The controller 2 may store the power supplied to the plurality of heaters 200, which is acquired in step ST34, in the storage 2a2 in association with one or more parameters.

Next, in step ST35, the second distribution data is calculated. The second distribution data may be distribution data of an ion flux generated between the plasma generated in the plasma process chamber 10 and the second substrate. The distribution data of the ion flux may be calculated based on the Formulas (4) and (5).

Next, in step ST36, a correction value is calculated based on the reference distribution data and the second distribution data. The correction value may be a difference value between the reference distribution data and the second distribution data. The correction value may be used as a correction value for distribution of an ion flux in plasma processing performed after the second substrate in a lot including the first substrate and the second substrate.

As an example, the present disclosure may include the following aspects.

### Supplementary Note 1

A plasma processing apparatus including:
a plasma process chamber;
a substrate support disposed within the plasma process chamber;
an antenna disposed above the plasma process chamber;
a source RF signal generator electrically connected to the antenna and configured to generate a source RF signal;
a bias signal generator electrically connected to the substrate support and configured to generate a bias signal;
an upper electromagnet unit disposed above the antenna and including a plurality of upper annular electromagnets arranged concentrically;
a sidewall electromagnet unit disposed to surround a sidewall of the plasma process chamber and including a plurality of sidewall annular electromagnets arranged along a vertical direction;
an electromagnet excitation circuit configured to supply a current to at least one of the plurality of upper annular electromagnets or the plurality of sidewall annular electromagnets; and
a controller configured to adjust the current supplied to at least one of the plurality of upper annular electromagnets or the plurality of sidewall annular electromagnets to control a plasma electron density distribution in the plasma process chamber.

### Supplementary Note 2

The plasma processing apparatus of Supplementary Note 1, wherein the plurality of upper annular electromagnets includes:
a first upper annular electromagnet;
a second upper annular electromagnet disposed to surround the first upper annular electromagnet;
a third upper annular electromagnet disposed to surround the second upper annular electromagnet; and
a fourth upper annular electromagnet disposed to surround the third upper annular electromagnet.

### Supplementary Note 3

The plasma processing apparatus of Supplementary Note 1 or 2, wherein the plurality of sidewall annular electromagnets includes:
a first sidewall annular electromagnet;
a second sidewall annular electromagnet disposed below the first sidewall annular electromagnet; and
a third sidewall annular electromagnet disposed below the second sidewall annular electromagnet.

### Supplementary Note 4

The plasma processing apparatus of any one of Supplementary Notes 1 to 3, wherein the substrate support includes a plurality of heaters, and
wherein the controller is further configured to:
acquire a power value supplied to each of the plurality of heaters; and
adjust the current supplied to at least one of the plurality of upper annular electromagnets or the plurality of sidewall annular electromagnets based on the acquired power value.

### Supplementary Note 5

The plasma processing apparatus of any one of Supplementary Notes 1 to 4, wherein the source RF signal repeats a first state having a first power level and a second state having a second power level smaller than the first power level, and
wherein the current repeats a first state having a first current level and a second state having a second current level smaller than the first current level based on the first state and the second state of the source RF signal.

### Supplementary Note 6

The plasma processing apparatus of Supplementary Note 5, wherein the first power level is a zero power level, and the first current level is a zero current level.

### Supplementary Note 7

The plasma processing apparatus of any one of Supplementary Notes 1 to 6, wherein the controller is configured to adjust the current supplied to at least one of the plurality of upper annular electromagnets or the plurality of sidewall annular electromagnets in a plasma ignition sequence.

### Supplementary Note 8

A plasma processing apparatus including:
a plasma process chamber;
a substrate support disposed within the plasma process chamber;
an antenna disposed above the plasma process chamber;
a source RF signal generator electrically connected to the antenna and configured to generate a source RF signal;
a bias signal generator electrically connected to the substrate support and configured to generate a bias signal;
an upper electromagnet unit disposed above the antenna and including a plurality of upper annular electromagnets arranged concentrically; and
an electromagnet excitation circuit configured to supply a current to at least one of the plurality of upper annular electromagnets.

### Supplementary Note 9

The plasma processing apparatus of Supplementary Note 8, wherein the plurality of upper annular electromagnets includes:
a first upper annular electromagnet; and
a second upper annular electromagnet disposed to surround the first upper annular electromagnet.

### Supplementary Note 10

The plasma processing apparatus of Supplementary Note 9, wherein the plurality of upper annular electromagnets further includes:
a third upper annular electromagnet disposed to surround the second upper annular electromagnet; and
a fourth upper annular electromagnet disposed to surround the third upper annular electromagnet.

### Supplementary Note 11

The plasma processing apparatus of any one of Supplementary Notes 8 to 10, wherein the substrate support includes a plurality of heaters,
the plasma processing apparatus further including: a controller configured to acquire a power value supplied to each of the plurality of heaters and adjust the current supplied to at least one of the plurality of upper annular electromagnets based on the acquired power value.

### Supplementary Note 12

A plasma processing apparatus including:
a plasma process chamber;
a substrate support disposed within the plasma process chamber;
an antenna disposed above the plasma process chamber;
a source RF signal generator electrically connected to the antenna and configured to generate a source RF signal;
a bias signal generator electrically connected to the substrate support and configured to generate a bias signal;
a sidewall electromagnet unit disposed to surround a sidewall of the plasma process chamber and including a plurality of sidewall annular electromagnets arranged along a vertical direction; and
an electromagnet excitation circuit configured to supply a current to at least one of the plurality of sidewall annular electromagnets.

### Supplementary Note 13

The plasma processing apparatus of Supplementary Note 12, wherein the plurality of sidewall annular electromagnets include:
a first sidewall annular electromagnet; and
a second sidewall annular electromagnet disposed below the first sidewall annular electromagnet.

### Supplementary Note 14

The plasma processing apparatus of Supplementary Note 13, wherein the plurality of sidewall annular electromagnets further include:
a third sidewall annular electromagnet disposed below the second sidewall annular electromagnet.

### Supplementary Note 15

The plasma processing apparatus of any one of Supplementary Notes 12 to 14, wherein the substrate support includes a plurality of heaters,
the plasma processing apparatus further including: a controller configured to acquire a power value supplied to each of the plurality of heaters and adjust the current supplied to at least one of the plurality of sidewall annular electromagnets based on the acquired power value.

According to one exemplary embodiment of the present disclosure, it is possible to provide a technique capable of adjusting the distribution of the thickness of an ion sheath.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus comprising:
a plasma process chamber;
a substrate support disposed within the plasma process chamber;
an antenna disposed above the plasma process chamber;
a source RF signal generator electrically connected to the antenna and configured to generate a source RF signal;
a bias signal generator electrically connected to the substrate support and configured to generate a bias signal;
an upper electromagnet unit disposed above the antenna and including a plurality of upper annular electromagnets arranged concentrically;
a sidewall electromagnet unit disposed to surround a sidewall of the plasma process chamber and including a plurality of sidewall annular electromagnets arranged along a vertical direction;
an electromagnet excitation circuit configured to supply a current to at least one of the plurality of upper annular electromagnets or the plurality of sidewall annular electromagnets; and
a controller configured to adjust the current supplied to at least one of the plurality of upper annular electromagnets or the plurality of sidewall annular electromagnets to control a plasma electron density distribution in the plasma process chamber.

2. The plasma processing apparatus of claim 1, wherein the plurality of upper annular electromagnets includes:
a first upper annular electromagnet;
a second upper annular electromagnet disposed to surround the first upper annular electromagnet;
a third upper annular electromagnet disposed to surround the second upper annular electromagnet; and
a fourth upper annular electromagnet disposed to surround the third upper annular electromagnet.

3. The plasma processing apparatus of claim 1, wherein the plurality of sidewall annular electromagnets includes:
a first sidewall annular electromagnet;
a second sidewall annular electromagnet disposed below the first sidewall annular electromagnet; and
a third sidewall annular electromagnet disposed below the second sidewall annular electromagnet.

4. The plasma processing apparatus of claim 3, wherein the substrate support includes a plurality of heaters, and
wherein the controller is further configured to:
acquire a power value supplied to each of the plurality of heaters; and
adjust the current supplied to at least one of the plurality of upper annular electromagnets or the plurality of sidewall annular electromagnets based on the acquired power value.

5. The plasma processing apparatus of claim 3, wherein the source RF signal includes a first power level in a first interval in each cycle and a second power level in a second interval in each cycle, the second power level being smaller the first power level, and
wherein the current includes a first current level in the first interval in each cycle and a second current level in the second interval in each cycle, the second current level being smaller than the first current level.

6. The plasma processing apparatus of claim 5, wherein the first power level is a zero power level, and the first current level is a zero current level.

7. The plasma processing apparatus of claim 3, wherein the controller is configured to adjust the current supplied to at least one of the plurality of upper annular electromagnets or the plurality of sidewall annular electromagnets in a plasma ignition sequence.

8. The plasma processing apparatus of claim 1, wherein the substrate support includes a plurality of heaters, and
wherein the controller is further configured to:
acquire a power value supplied to each of the plurality of heaters; and
adjust the current supplied to at least one of the plurality of upper annular electromagnets or the plurality of sidewall annular electromagnets based on the acquired power value.

9. The plasma processing apparatus of claim 1, wherein the source RF signal includes a first power level in a first interval in each cycle and a second power level in a second interval in each cycle, the second power level being smaller the first power level, and
wherein the current includes a first current level in the first interval in each cycle and a second current level in the second interval in each cycle, the second current level being smaller than the first current level.

10. The plasma processing apparatus of claim 1, wherein the controller is configured to adjust the current supplied to at least one of the plurality of upper annular electromagnets or the plurality of sidewall annular electromagnets in a plasma ignition sequence.

11. A plasma processing apparatus comprising:
a plasma process chamber;
a substrate support disposed within the plasma process chamber;
an antenna disposed above the plasma process chamber;
a source RF signal generator electrically connected to the antenna and configured to generate a source RF signal;
a bias signal generator electrically connected to the substrate support and configured to generate a bias signal;
an upper electromagnet unit disposed above the antenna and including a plurality of upper annular electromagnets arranged concentrically; and
an electromagnet excitation circuit configured to supply a current to at least one of the plurality of upper annular electromagnets.

12. The plasma processing apparatus of claim 11, wherein the plurality of upper annular electromagnets includes:
a first upper annular electromagnet; and
a second upper annular electromagnet disposed to surround the first upper annular electromagnet.

13. The plasma processing apparatus of claim 12, wherein the plurality of upper annular electromagnets further includes:
a third upper annular electromagnet disposed to surround the second upper annular electromagnet; and
a fourth upper annular electromagnet disposed to surround the third upper annular electromagnet.

14. The plasma processing apparatus of claim 13, wherein the substrate support includes a plurality of heaters,
the plasma processing apparatus further comprising: a controller configured to acquire a power value supplied to each of the plurality of heaters and adjust the current supplied to at least one of the plurality of upper annular electromagnets based on the acquired power value.

15. The plasma processing apparatus of claim 11, wherein the substrate support includes a plurality of heaters,
the plasma processing apparatus further comprising: a controller configured to acquire a power value supplied to each of the plurality of heaters and adjust the current supplied to at least one of the plurality of upper annular electromagnets based on the acquired power value.

16. A plasma processing apparatus comprising:
a plasma process chamber;
a substrate support disposed within the plasma process chamber;
an antenna disposed above the plasma process chamber;
a source RF signal generator electrically connected to the antenna and configured to generate a source RF signal;
a bias signal generator electrically connected to the substrate support and configured to generate a bias signal;
a sidewall electromagnet unit disposed to surround a sidewall of the plasma process chamber and including a plurality of sidewall annular electromagnets arranged along a vertical direction; and
an electromagnet excitation circuit configured to supply a current to at least one of the plurality of sidewall annular electromagnets.

17. The plasma processing apparatus of claim 16, wherein the plurality of sidewall annular electromagnets includes:
a first sidewall annular electromagnet; and
a second sidewall annular electromagnet disposed below the first sidewall annular electromagnet.

18. The plasma processing apparatus of claim 17, wherein the plurality of sidewall annular electromagnets further includes:
a third sidewall annular electromagnet disposed below the second sidewall annular electromagnet.

19. The plasma processing apparatus of claim 18, wherein the substrate support includes a plurality of heaters,
the plasma processing apparatus further comprising: a controller configured to acquire a power value supplied to each of the plurality of heaters and adjust the current supplied to at least one of the plurality of sidewall annular electromagnets based on the acquired power value.

20. The plasma processing apparatus of claim 16, wherein the substrate support includes a plurality of heaters,
the plasma processing apparatus further comprising: a controller configured to acquire a power value supplied to each of the plurality of heaters and adjust the current supplied to at least one of the plurality of sidewall annular electromagnets based on the acquired power value.
